(19) United States
(12) Patent Application Publication
(10) Pub. No.: US 2026/0071981 A1
(43) Pub. Date: Mar. 12, 2026

(54) Method for generating and/or detecting a magnetization, magnetometer and spectroscopy apparatus

(71) Applicant: Universitaet Stuttgart, Stuttgart (DE)

(72) Inventors: Jens Anders, Stuttgart (DE); Muhammad Khubaib Ul Hassan Khan, Stuttgart (DE)

(21) Appl. No.: 19/314,156

(22) Filed: Aug. 29, 2025

(30) Foreign Application Priority Data
Sep. 6, 2024 (EP) 24198827.8

(51) Int. Cl. G01N 24/08; G01N 24/10; G01R 33/46

(52) U.S. Cl. CPC G01N 24/08; G01N 24/10; G01R 33/46

(57) ABSTRACT

A method for generating and/or detecting a magnetization of a sample at a sample location by means of electron spin resonance spectroscopy or for the measurement of a first magnetic field (B₀) acting on the sample at the sample location. An inductive assembly is excited by an excitation signal (S) to provide a second magnetic field (B₁) at the sample location, wherein the excitation signal (S) is switched cyclically between an excitation period (TX), in which an operating frequency (f_{ESR}) of the excitation signal(S) has a sample-specific resonant frequency (fᵣₑₛ), and an idle period (RX), in which the operating frequency (f_{ESR}) of the excitation signal (S) has an idle frequency (f_{idle}) different than the resonant frequency (fᵣₑₛ). An operating phase of the excitation signal (S) is matched to an excitation reference phase of an excitation reference signal (S_{ref}), which is separate from the excitation signal (S).

### FIELD AND BACKGROUND OF THE INVENTION

The invention relates to a method for generating and/or detecting a magnetization of a sample at a sample location, in particular for the examination of the sample by means of electron spin resonance spectroscopy or for the measurement of a first magnetic field acting on the sample at the sample location.

The invention furthermore relates to a magnetometer for measuring a first magnetic field by generating and/or detecting a magnetization of a sample at a sample location, in particular a nuclear magnetic resonance-based magnetometer or an electron spin resonance-based magnetometer, comprising an inductive assembly and a control device.

The invention additionally relates to a spectroscopy apparatus for examining a sample at a sample location, in particular an electron spin resonance spectroscopy apparatus or a nuclear magnetic resonance spectroscopy apparatus, comprising a device for generating a first magnetic field at the sample location, an inductive assembly and a control device.

Magnetic field sensors or magnetometers are found in many technological applications. They detect and measure magnetic fields and make it possible to obtain information about the magnetic environment.

Magnetic field sensors play an important part in medical technology, inter alia, where they are used in magnetic resonance imaging (MRI), for example, in order highly accurately to measure the magnetic field provided for the imaging, to determine and subsequently compensate for inhomogeneities of this magnetic field, and thus to create detailed images of inside the body.

Magnetic field sensors also find application in electron spin resonance spectroscopy (ESR), sometimes also referred to as EPR (“electron paramagnetic resonance spectroscopy”), which is used inter alia for measuring radicals in foodstuffs and medically relevant samples (e.g. blood samples, but also medicaments). In the case of electron spin resonance spectroscopy, the samples in a statically homogeneous, statically inhomogeneous or dynamic (pulsed inhomogeneous) magnetic field, usually referred to as B₀ (hereinafter: “first magnetic field”), are exposed to additional high-frequency alternating electromagnetic fields, usually referred to as B₁ (hereinafter: “second magnetic field”). The incoupling of these additional alternating fields induces transitions between the energy levels of discrete spin states of the atomic nuclei (NMR) and/or electrons (ESR, DNP, ENDOR) of a sample, which in turn lead to absorption processes in the alternating field which are able to be detected. Various items of substance-analytical information pertaining to the sample can be determined from the detected absorption processes. Electron spin resonance spectroscopy is therefore a powerful method which utilizes the spin of an unpaired electron as a nanoscopic probe within a molecule in order to obtain information about the chemical structure and composition of the sample through small changes in the resonant frequency. The samples may be liquid, solid or else gaseous. Especially the examination of reaction kinetics or sequences/changes in biological or chemical processes requires a particularly fast and highly precise magnetic field measurement and control, since even fluctuations over short time intervals may directly influence the quality of the measurement results.

A similar method is nuclear magnetic resonance (NMR) spectroscopy, which can be applied to samples having atomic nuclei with “net nuclear spin” owing to an odd number of nucleons.

For further technological background concerning ESR and NMR, reference should be made at this juncture to DE 10 2016 102 025 A1, by way of example.

In recent years, various concepts have been disclosed for oscillator-based CMOS-integrated ESR detectors (“EPR/ESR-on-a-chip”) for various fundamental frequencies up to 146 GHz. For example, voltage-controlled oscillators (VCOs) in the form of electron spin resonance (ESR) sensors were proposed in 2016 in the publication by Handwerker, J. et al. “A 14 GHz battery-operated point-of-care ESR spectrometer based on a 0.13 μm CMOS ASIC”, IEEE International Solid-State Circuits Conference (ISSCC), pp. 476-477.

Systems which overall are more compact and more cost-effective and nevertheless have high performance can be provided especially through the use of voltage-controlled LC oscillators for generating the second magnetic field B₁. Corresponding VCO-based B₁ sources afford many advantages, including the possibility of inductively detecting the spin magnetization as early as during the excitation pulses, but suffer from the fact that the limited quality factor of the embedded LC resonator requires a lower threshold value for the minimum oscillation current within the inductor. Since the tank inductor of the VCO is directly coupled to the spin ensemble, without the possibility of switching the B₁ field on and off as necessary, VCO-based pulsed excitation signals require the switching of the VCO operating frequency to and from the sample-specific resonant frequency.

However, the switching of the operating frequency leads to a loss of phase information between successive excitation pulses or excitation periods. The loss of coherence makes the evaluation of the response signal of the sample more difficult or significantly reduces the measurement accuracy.

In order to solve the aforementioned coherence problem, the publication by M. Hassan et. al., “Towards single-cell pulsed EPR using VCO-based EPR-on-a-chip detectors”, Frequenz, vol. 76, no. 11-12, pp. 699-717, Sept. 2022, proposes a control loop for correcting the phase of the excitation signal. However, the proposed technology is comparatively complex and there is moreover the need to increase the measurement accuracy even further. This is because the phase stabilization should preferably take place in the picoseconds range and the requisite bandwidth in the phase locked loop (PLL) is not straightforwardly attainable from a technical standpoint. The delay during phase matching may therefore still lead to significant coherence losses, which in turn adversely affects the accuracy and sensitivity of the measurements.

### SUMMARY OF THE INVENTION

In view of the known prior art, the object of the present invention consists in providing a method for generating and/or detecting a magnetization of a sample by means of which a particularly high measurement accuracy is achievable, preferably using pulsed excitation signals generated by means of a voltage-controlled oscillator.

The present invention is also based on the object of providing a magnetometer which enables a particularly high measurement accuracy to be achieved, preferably using pulsed excitation signals generated by means of a voltage-controlled oscillator.

Finally, it is also an object of the invention to provide a spectroscopy apparatus which enables a particularly high measurement accuracy to be achieved, preferably using pulsed excitation signals generated by means of a voltage-controlled oscillator.

The object is achieved for the method with the features presented herein. The object is achieved by the features disclosed herein with regard to the magnetometer and by the features disclosed herein with regard to the spectroscopy apparatus.

A method for generating and/or detecting a magnetization of a sample at a sample location is provided, wherein an inductive assembly is excited by an excitation signal in order to provide a second magnetic field at the sample location.

The method according to the invention is advantageously suitable in particular for a spectroscopic examination of the sample (e.g. by means of electron spin resonance spectroscopy or nuclear magnetic resonance spectroscopy) or for the measurement of an external magnetic field (referred to hereinafter as “first magnetic field”) acting on the sample at the sample location.

According to the invention, the excitation signal is switched cyclically between an excitation period, in which an operating frequency of the excitation signal has a sample-specific resonant frequency, and an idle period, in which the operating frequency of the excitation signal has an idle frequency different than the resonant frequency.

During the excitation period of the excitation signal, it is thus possible to generate an “excitation pulse” that is temporally spaced apart from the subsequent excitation pulse by the succeeding idle period of the excitation signal. In the context of the present invention, an “excitation pulse” is understood to mean an electrical signal which is fed to the inductive assembly and which can be functionally suitable for generating a second magnetic field. In particular, the excitation pulses can have a sufficiently large amplitude and a suitable frequency in order to suitably deflect the magnetization of the sample proceeding from its initial or equilibrium state.

Provision can be made for the temporal spacing between all directly successive excitation pulses to be identical. In principle, however, provision can also be made for the temporal spacing between at least two successive excitation pulses to be different.

Preferably (but not necessarily), the inductive assembly can be arranged and oriented in such a way that the second magnetic field at the sample location is oriented at least substantially orthogonally to the first magnetic field since, in conventional ESR, only orthogonal components of the second magnetic field can bring about a corresponding deflection of the magnetization of the sample. The second magnetic field can thus have at least one component oriented orthogonally to the first magnetic field.

The inductive assembly can be an inductive assembly of arbitrary design which is advantageously suitable for providing the second magnetic field in the context of the applications mentioned above. In particular, the inductive assembly can comprise one or more inductive elements (e.g. “plate-type” or planar inductive elements formed from a metal material or inductive elements formed from a coil wire).

Preferably, the sample location is arranged in the near field of the inductive assembly. If appropriate, however, the sample location can also be arranged in the far field of the inductive assembly.

The first magnetic field can preferably be a static or a quasi-static magnetic field.

Solid, gaseous and/or liquid samples are conceivable as samples. Liquid samples can be secured e.g. in glass capillaries on or in circuit components (e.g. also using CMOS technology). At lower frequencies of the first magnetic field down to the so-called X-band (approximately 10 Ghz), the coils of the inductive assembly can optionally also be realized as volume coils into which the capillaries with liquid samples can be introduced. The method (or a corresponding apparatus) can optionally also be implemented within the liquid, gas or solid to be measured, in order for example to detect phase transitions and transitions of states of matter.

It should be mentioned at this juncture that, in the context of the present invention, in principle an arbitrary number of excitation pulses or excitation periods can be provided, but at least two successive excitation pulses or excitation periods. In general, increasing the number of excitation pulses/excitation periods or the number of corresponding measurements can increase the measurement accuracy. It may therefore be necessary to weigh measurement duration against precision in a manner governed by the application.

The excitation pulse or the excitation signal in the excitation period (and optionally also the excitation signal in the idle period) can preferably be a periodic signal, such as for example a sine signal. In particular, a square-wave signal can be provided as envelope or envelope curve of the excitation signal, although other waveforms can also be appropriate as envelope, such as for example a Gaussian curve. The periodic signal of the excitation signal can also be any desired signal, in principle, and need not necessarily correspond to a sine. In particular, however, the combination of a square-wave signal as envelope with a sine signal has proved to be particularly suitable for the envisaged applications, since this constitutes the technically simplest realization, which in general is sufficient as well.

In the context of the present invention, the pulse duration of the individual excitation pulses can be arbitrary, but the excitation pulse preferably contains at least one period of the aforementioned periodic signal, preferably at least two, three, for example four, five or even more periods (in principle, however, the excitation pulse can also contain just a fraction of a period of the periodic signal).

The pulse duration of the successive excitation pulses can preferably be identical. In principle (depending on experiment or application), however, provision can also be made for the pulse duration between at least two successive excitation pulses to be different. The use of phase-coherent excitation pulses with variable spacing can be advantageous for example for measuring distances in molecules (so-called PELDOR or DEER spectroscopy).

The invention provides for an operating phase of the excitation signal, at least in the context of switching the operating frequency from the idle frequency to the resonant frequency, to be matched to an excitation reference phase of an excitation reference signal, which is separate from the excitation signal (optionally, however, the aforementioned matching can also take place at other points in time, as will also be mentioned below, i.e. for example also when switching from the excitation to the measurement).

Preferably, the excitation reference signal is generated continuously during the method.

In other words, provision can be made for the individual excitation pulses (and/or the readout pulses that will also be mentioned below) to be generated from individual time segments of a common, continuous reference signal. Consequently, the periodic signal of the reference signal can preferably be generated continuously and be used only at times for the matching of the operating phase of the excitation signal. Consequently, the phase coherence and-if necessary or desired-even phase coincidence of all the excitation pulses and/or readout pulses can be ensured using technically simple means.

The proposed invention thus solves the problem of the loss of phase information when switching the excitation signal for the Bi magnetic field between two successive excitation pulses by way of the operating phase of the excitation signal, at least during the excitation pulses, being matched to the phase of a preferably continuously proceeding or continuously operated excitation reference signal.

In an advantageous manner, a phase-coherent or in-phase progression of the excitation pulses (and optionally also of the readout pulses also mention below) can thus be made possible in the context of the invention. In the context of the invention, an “in-phase progression” is understood to mean that each succeeding excitation or readout pulse starts in a phase position in which the directly preceding excitation or readout pulse would have been at the same point in time if it had not been interrupted. In the context of the invention, a “phase-coherent progression” is understood to mean in particular that each succeeding excitation or readout pulse is in phase coherence with preceding pulses, also irrespective of whether the phase of the excitation pulses is changed (e.g. switched in a targeted manner).

The proposed method enables the temporal spacing between individual excitation or readout pulses to be chosen arbitrarily, which increases the flexibility of the method and can be used for example to considerably increase the measurement speed. By virtue of the excitation and/or readout pulses progressing phase-coherently, the evaluation of the response signal of the sample can be simplified and the measurement accuracy can be increased.

The excitation signal can be provided in any desired way, in principle. In one particularly advantageous development of the invention, however, provision can be made for the excitation signal to be generated by a primary voltage-controlled oscillator (VCO), Preferably, the primary voltage-controlled oscillator is a voltage-controlled oscillator based on an LC resonant circuit. In principle, however, the resonant circuit can be realized in any desired way, although LC VCOs are in general particularly well suited to the envisaged application.

In accordance with one development of the invention, it can be provided that the operating phase of the excitation signal, in the context of switching the operating frequency from the resonant frequency to the idle frequency, is matched to a readout reference phase of a readout reference signal, which is separate from the excitation signal and is preferably generated continuously.

Preferably, the readout reference signal is different than the excitation reference signal. In the context of the invention, therefore, it is also possible to ensure as necessary that when switching the excitation signal between two successive idle periods, a phase loss does not occur by virtue of the operating phase of the excitation signal during the idle period being matched to the phase of a preferably further continuously proceeding or continuously operated reference signal.

Provision can be made for the temporal spacing between directly successive excitation pulses (i.e. the readout duration) to be identical in each case. In principle (less preferably), however, provision can also be made for the readout duration to be variable.

In accordance with one development of the invention, it can be provided that the excitation reference signal is generated by a first secondary voltage-controlled oscillator and/or the readout reference signal is generated by a second secondary voltage-controlled oscillator.

Preferably, but not necessarily, the secondary voltage-controlled oscillators can once again be LC-based VCOs.

The primary voltage-controlled oscillator can thus be connected, in a particularly advantageous way, to the first and/or second secondary voltage-controlled oscillator by “injection locking” for the purpose of matching the operating phase to the respective reference. The process of “injection locking” of voltage-controlled oscillators is known in the literature and can enable the phases to be matched in an extremely short time (as little as a few picoseconds).

It should be emphasized that the phase of the excitation reference signal and/or of the readout reference signal can be adjustable or switchable as necessary.

In order optionally to enable excitation and/or readout pulses with different phases, one development of the invention can provide for the first secondary voltage-controlled oscillator and/or the second secondary voltage-controlled oscillator to be embodied as a voltage-controlled multi-phase oscillator.

Preferably a multiplexer can be used for selecting as necessary from the different output signals of the multi-phase oscillator, which are phase-shifted with respect to one another.

In particular, provision can be made for the multi-phase oscillator to provide two, three, four, five, six or more different output signals phase-shifted with respect to one another (if there are four output signals, these can e.g. each be phase-shifted by 90° with respect to one another), which allow selectability therefrom as necessary in order to match the operating phase of the excitation signal thereto.

In one development of the invention, it can be provided that matching the operating phase to the excitation reference phase and/or to the readout reference phase is effected by injection locking of the primary voltage-controlled oscillator with the first secondary voltage-controlled oscillator and/or with the second secondary voltage-controlled oscillator, respectively.

However, the matching (i.e. approximating up to preferably, but not necessarily, complete correspondence) of the operating phase to the reference phases need not necessarily be effected by injection locking, but rather can also be effected by an alternative technical implementation in the context of the invention.

In one advantageous development of the invention, it can be provided that the primary voltage-controlled oscillator has applied to it a first input signal for generating the resonant frequency in the excitation period and a second input signal for generating the idle frequency in the idle period.

In one development of the invention, it can be provided that at least two of the directly successive excitation periods, preferably all of the excitation periods, progress phase-coherently with respect to one another. The same can apply, mutatis mutandis, to the optional idle or readout periods.

In one advantageous development of the invention, it can be provided that the resonant frequency is increased at least by a factor of 2, preferably is increased at least by a factor of 1.5, particular preferably is increased at least by a factor of 1.05, relative to the idle frequency. By way of example, a bandwidth of at least 100 Mhz can be sufficient for covering an ESR spectrum.

In one advantageous development of the invention, it can be provided that the inductive assembly is excited by the excitation signal without interruption.

Preferably, therefore, the excitation signal is not switched on and off. Therefore, preferably only the operating frequency is switched for the purpose of providing the temporally spaced apart excitation pulses. In this way, long settling processes of the oscillators involved can advantageously be avoided.

Preferably, during the idle period of the excitation signal, the inductive assembly is used as a sensor element for detecting the electromagnetic response signal of the sample. Various methods are already known in respect of this, for which reason reference should be made to the relevant technical literature in regard to further background. The idle period of the excitation signal can therefore also be referred to as a “readout period”. The excitation signal, in the idle period, can optionally provide “readout pulses” suitable for reading out the response signals of the sample.

In one advantageous development of the invention, therefore, it can be provided in particular that the response signal of the sample is detected by means of the inductive assembly during the idle period of the excitation signal and is evaluated by a control device.

The control device can be embodied as a microprocessor. Instead of a microprocessor, it is also possible to provide any other device for implementing the control device, for example one or more arrangements of discrete electrical components on a printed circuit board, a programmable logic controller (PLC), an application-specific integrated circuit (ASIC) or some other programmable circuit, for example also a field programmable gate array (FPGA), a programmable logic array (PLA) and/or a commercially available computer.

Preferably, the control device is a circuit component of an integrated circuit.

In one development of the invention, it can be provided that an operating amplitude of the excitation signal is reduced, preferably is reduced at least to 50%, particularly preferably is reduced at least to 20%, more preferably is reduced at least to 10%, in the idle period relative to the excitation period.

In an advantageous way, the proposed principle can be extended by virtue of switching the amplitude of the oscillation or of the excitation signal between the pulsed excitation (i.e. the VCO operating frequency at resonance) and the subsequent detection (i.e. the VCO operating frequency outside resonance) in order to increase the excitation efficiency or in order to optimize the detection sensitivity.

The invention also relates to a magnetometer for measuring a first magnetic field by generating and/or detecting a magnetization of a sample at a sample location, comprising an inductive assembly and a control device configured to excite the inductive assembly by an excitation signal in order to provide a second magnetic field at the sample location.

The magnetometer can be in particular a nuclear magnetic resonance-based magnetometer (NMR magnetometer) or an electron spin resonance-based magnetometer (ESR magnetometer).

It should be mentioned at this juncture that the sample and/or the sample location need not necessarily be part of the magnetometer. The sample and/or the sample location can also be independent of the magnetometer. Preferably, however, the sample and/or the sample location can be a component of the magnetometer. This analogously also applies to the spectroscopy apparatus also mentioned below.

The sample location can preferably comprise means for securing and storing the sample.

According to the invention, for the magnetometer it is provided that the excitation signal is switched cyclically between an excitation period, in which an operating frequency of the excitation signal has a sample-specific resonant frequency, and an idle period, in which the operating frequency of the excitation signal has an idle frequency different than the resonant frequency. At least in the context of switching the operating frequency of the excitation signal from the idle frequency to the resonant frequency, an operating phase of the excitation signal is matched or at least approximated to an excitation reference phase of an excitation reference signal, which is separate from the excitation signal and is preferably generated continuously.

The proposed excitation technology makes possible not only a highly accurate magnetic field measurement but also, in comparison with the known magnetometers, a significantly faster magnetic field measurement.

In accordance with one development of the invention, it can be provided that the inductive assembly and the control device are arranged on a common integrated circuit.

Preferably, provision can additionally also be made for the sample location and/or the sample to be arranged on the common integrated circuit. Consequently, a magnetometer based completely on an integrated circuit can preferably be provided.

Therefore, a chip-based ESR or NMR magnetometer can advantageously be provided. By virtue of the integration of preferably the entire electronics and optionally also the sample location and the sample in or on a single miniaturized chip, it is possible to integrate the sensor in an advantageous application for example directly in the magnetic field of an MRI system and thus for the first time to enable a virtually continuous magnetic field measurement during ongoing operation of the MRI system. By virtue of the measurement of the magnetic field of the MRI system in real time, movement artefacts can be minimized, much higher-resolution MRI images can be generated and the entire medical imaging can thus be improved. In addition, faster imaging increases not only patient convenience but also diagnosis efficiency.

Therefore, the invention also relates to an MRI system, comprising a magnetometer in accordance with the embodiments above and below. The magnetometer can be usable within the MRI system in order to improve the imaging, as indicated above.

The invention also relates to a spectroscopy apparatus for examining a sample at a sample location, comprising a device for generating a first magnetic field at the sample location, an inductive assembly and a control device configured to excite the inductive assembly by an excitation signal in order to provide a second magnetic field at the sample location.

The spectroscopy apparatus is preferably an ESR spectroscopy apparatus or an NMR spectroscopy apparatus.

The device for generating the first magnetic field can be designed in particular to provide a static (or quasi-static) first magnetic field with predetermined direction and strength at the sample location. The device for generating the first magnetic field can be realizable for example by superconducting magnets or electromagnets of any desired embodiment or by permanent magnets.

The first magnetic field is preferably static and corresponds to the magnetic field Bo already mentioned above, which serves for magnetization of a sample suitable for magnetization. The first magnetic field can be of arbitrary strength, in principle, as long as the frequency of the exciting B₁ magnetic field (“second magnetic field”) is chosen according to the resonance conditions or the so-called Larmor frequency of the sample.

According to the invention, the excitation signal is switched cyclically between an excitation period, in which an operating frequency of the excitation signal has a sample-specific resonant frequency, and an idle period, in which the operating frequency of the excitation signal has an idle frequency different than the resonant frequency. It is provided that, at least in the context of switching the operating frequency of the excitation signal from the idle frequency to the resonant frequency, an operating phase of the excitation signal is matched or at least approximated to an excitation reference phase of an excitation reference signal, which is separate from the excitation signal and is preferably generated continuously.

It can be provided that the spectroscopy apparatus comprises an evaluation circuit for processing an output voltage of the inductive assembly, wherein the evaluation circuit preferably comprises means for demodulation, analog-to-digital conversion and/or means for digital data processing. Corresponding evaluation circuit switches which can be suitable for evaluating the output signal of the sample are known in principle.

It can be provided that the evaluation circuit is configured to determine the magnetization of the sample and the spin concentration of individual spectral components that is to be ascertained therefrom.

The invention makes it possible to provide a particularly fast and highly precise magnetic field measurement for ESR applications, for example. One possible further advantageous application of the method according to the invention concerns medical technology (for example MRI systems), as already mentioned above.

Features which have been described in connection with one of the subjects of the invention, which are specifically the method according to the invention, the magnetometer according to the invention, the MRI system according to the invention and the spectroscopy apparatus according to the invention, are also advantageously implementable for the other subjects of the invention. Likewise, advantages specified in connection with one of the subjects of the invention can also be understood in relation to the other subjects of the invention.

At this point, it should be noted that the term “connected” or “connection” used in the present description and in the patent claims can describe a direct electrical connection of the stated components, but also an indirect electrical connection of the stated components (i.e. e.g. via further electrical lines or electronic components such as resistors, inductors and/or capacitors, etc.). The term “attached” or “contacted”, on the other hand, usually indicates a direct connection of the stated components.

It should additionally be emphasized that method steps need not necessarily be carried out in the order in which they are first described or mentioned in the description or in the patent claims. For example, individual method steps or groups of method steps can therefore be interchangeable if this is not technically excluded. Method steps can also be combined with each other, divided into separate intermediate steps or supplemented with intermediate steps. The method according to the invention is also not necessarily exhaustively described with the described method steps and can be extended with further method steps, also not mentioned.

In addition, it should be noted that terms such as “comprising”, “having” or “with” do not exclude other features or steps. Furthermore, terms such as “a/an” or “the” indicating steps or features in the singular do not exclude a plurality of features or steps-and vice versa.

It should be mentioned that labels such as “first” or “second” etc. are used predominantly for the sake of distinguishability between respective apparatus or method features, and are not necessarily intended to indicate that features are mutually dependent or related to one another.

Furthermore, it should be emphasized that the values and parameters described in the present case also encompass deviations or fluctuations of ±10% or less, preferably ±5% or less, more preferably ±1% or less, and very particularly preferably ±0.1% or less, of the respectively stated value or parameter, provided that these deviations are not excluded in practice when implementing the invention. The specification of ranges by way of start and end values also encompasses all values and fractions encompassed by the respectively stated range, in particular the start and end values and a respective mean value.

Exemplary embodiments of the invention will be described in more detail below with reference to the drawings.

### BRIEF DESCRIPTION OF THE DRAWINGS

The figures each show preferred exemplary embodiments in which individual features of the present invention are illustrated in combination with one another. Features of one exemplary embodiment are also implementable separately from the other features of the same exemplary embodiment, and can accordingly be readily combined by a person skilled in the art to form further useful combinations and sub-combinations with features of other exemplary embodiments.

In the figures, functionally identical elements are provided with the same reference signs.

In the figures, in each case schematically:

FIG. 1 shows a magnetometer and a spectroscopy apparatus in accordance with one exemplary embodiment of the invention;

FIG. 2 shows an exemplary excitation signal for the magnetometer or the spectroscopy apparatus in accordance with FIG. 1;

FIG. 3 shows one exemplary implementation of the method according to the invention;

FIG. 4 shows a further exemplary implementation of the method according to the invention;

FIG. 5 shows a further exemplary implementation of the method according to the invention;

FIG. 6 shows simulation results of the proposed method for elucidating the principle of matching the operating phase of the excitation signal to the excitation reference signal by injection locking;

FIG. 7 shows simulation results of the proposed method for representing a detected ESR signal after an excitation pulse; and

FIG. 8 shows a further exemplary implementation of the method according to the invention.

### DESCRIPTION OF THE PREFERRED EMBODIMENTS

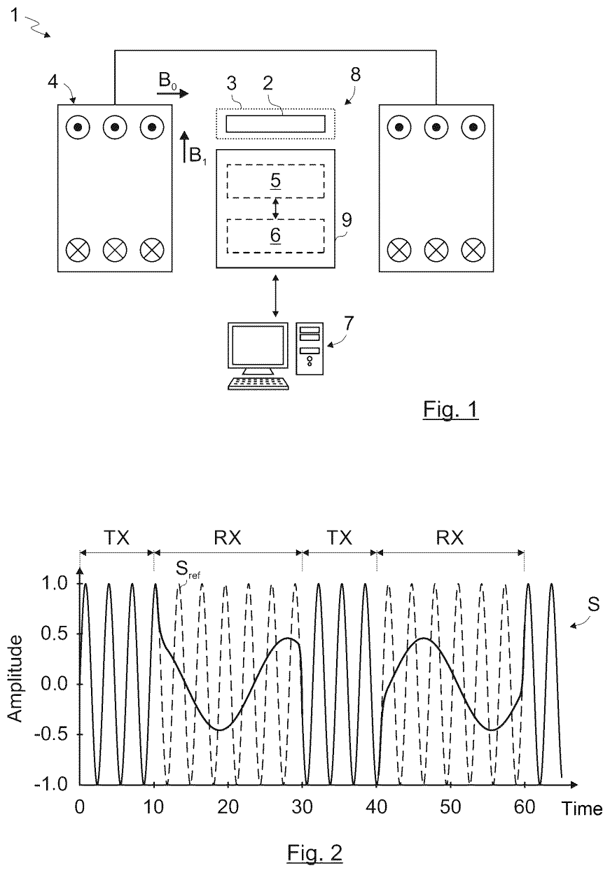

FIG. 1 illustrates by way of example a spectroscopy apparatus 1 for examining a sample 2 at a sample location 3, this apparatus being of the kind that can be used in the context of electron spin resonance spectroscopy or nuclear magnetic resonance spectroscopy according to the present invention. Since the fundamental principle of an ESR or NMR spectroscopy apparatus is known, this principle will merely be described in a basic way below. For further details, reference should be made to the relevant literature.

The spectroscopy apparatus 1 comprises a device 4 for generating or providing a (preferably static) first magnetic field B₀ at the sample location 3. The device 4 can be embodied for example as a magnet, for example a superconducting magnet (e.g. a 9.4 T magnet), an electromagnet of any desired embodiment, a permanent magnet or an internal, sample-intrinsic magnet (e.g. dipole fields). In the sample 2, the first magnetic field B₀ induces a magnetization according to the susceptibility of the sample 2.

The spectroscopy apparatus 1 additionally comprises an inductive assembly 5 and also a control device 6 in order to excite the inductive assembly 5 by an excitation signal S, in order to provide an additional, second magnetic field B₁ at the sample location 3. The control device 6 is configured to generate the second magnetic field B₁ by means of the inductive assembly 5 in such a way that the magnetization of the sample 2 is deflected from its equilibrium position. Especially in the case of conventional transverse ESR, the second magnetic field B₁ is oriented orthogonally to the first magnetic field B₀ or has at least one component orthogonal to the first magnetic field B₀ (it should be mentioned, however, that longitudinal ESR methods can also be employed in the context of the invention). The inductive assembly 5 and the control device 6 are each merely indicated schematically as a black box in FIG. 1.

In order subsequently also to detect the magnetization of the sample 2, a response signal detected from the sample 2 via the inductive assembly 5 can be transferred to an evaluation circuit 7. The evaluation circuit 7 can preferably comprise means for demodulation, analog-to-digital conversion and/or means for digital data processing and is merely indicated by way of example in FIG. 1. The evaluation circuit 7 can be configured to determine the magnetization of the sample 2 and the spin concentration of individual spectral components that is ascertained therefrom. Provision can be made for the evaluation circuit 7 to be part of the control device 6—or vice versa.

However, the invention can also be advantageously suitable for use in a magnetometer 8 or as a magnetometer 8 for measuring the first magnetic field B₀. In other words, if an external, first magnetic field B₀ is to be examined metrologically, it is possible, by means of the magnetometer 8 according to the invention, to generate the second magnetic field B₁ via the inductive assembly 5 excited by means of the excitation signal S and to determine the first magnetic field B₀ in conjunction with known material properties of the sample 2.

Preferably, all electronic components and/or the sample location 3 and/or the sample 2 can be arranged on a common integrated circuit 9. A corresponding magnetometer 8 can be advantageously suitable for example for image correction within an MRI system (not illustrated).

A method for generating and/or detecting a magnetization of the sample 2 at a sample location 3 is thus proposed, in particular for the examination of the sample 2 by means of ESR spectroscopy or NMR spectroscopy or for the measurement of a first magnetic field B₀ acting on the sample 2 at the sample location 3.

In the context of the invention, it is provided that the excitation signal S is switched cyclically between an excitation period TX, in which an operating frequency f_{ESR} of the excitation signal S has a sample-specific resonant frequency fᵣₑₛ, and an idle period RX, in which the operating frequency f_{ESR} of the excitation signal S has an idle frequency f_{idle} different than the resonant frequency fᵣₑₛ.

An exemplary excitation signal S for the proposed magnetometer 8 or for the proposed spectroscopy apparatus 1 is indicated in FIG. 2. Provision can be made for the inductive assembly 5 to be excited by the excitation signal S without interruption (or at least substantially without interruption). In the idle period RX, however, the operating frequency f_{ESR} of the excitation signal S can be reduced, preferably at least by a factor of 2, relative to the resonant frequency fᵣₑₛ. The amplitude (“operating amplitude”) of the excitation signal S can also optionally be reduced in the idle period RX, preferably (but not necessarily) at least by a factor of 2, which is likewise indicated schematically in FIG. 2.

In the context of the invention, it is further provided that an operating phase of the excitation signal S, at least in the context of switching the operating frequency f_{ESR} from the idle frequency f_{idle} to the resonant frequency fᵣₑₛ, is matched to an excitation reference phase of an excitation reference signal S_{ref}, which is separate from the excitation signal S and is preferably generated continuously. In this way, it can preferably be ensured that at least two directly successive excitation periods TX, preferably all of the excitation periods TX, progress phase-coherently with respect to one another. For elucidation, in FIG. 2 the excitation reference signal S_{ref} is indicated as progressing continuously by dashed lines.

By virtue of the fact that the loss of phase information when switching the excitation signal S between two successive excitation pulses is avoided in the context of the invention, the evaluation of the response signal of the sample 2 can be simplified and the measurement accuracy can be increased (some measurements can actually be made possible in the first place as a result of this). The use of the excitation reference signal S_{ref} enables the operating phase of the excitation signal S to be matched directly after the switching time in a particularly simple and rapid manner, as a result of which the temporal spacing between individual excitation or readout pulses can be reduced and the measurement speed of the method can thus be considerably increased by comparison with the prior art.

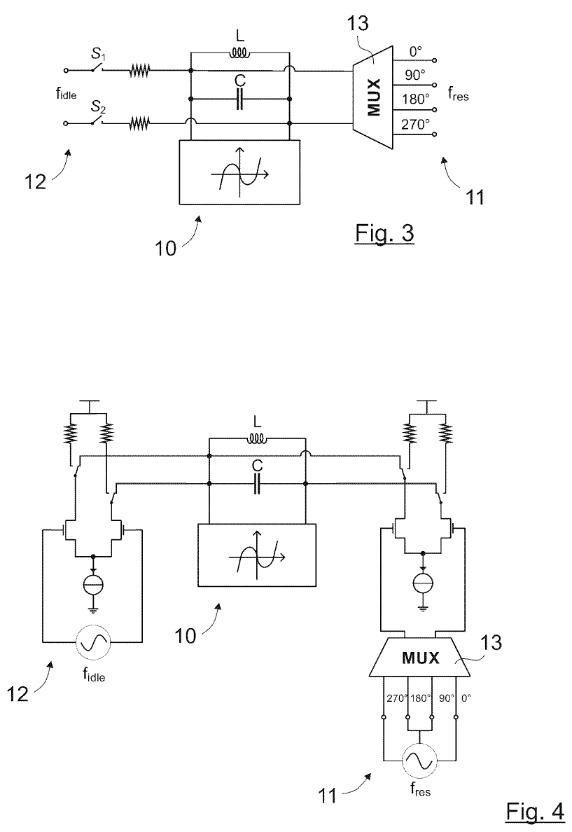

FIG. 3 schematically shows one possible implementation of the proposed method, and one exemplary implementation specified with more concrete details is indicated in FIG. 4.

The excitation signal S for generating the second magnetic field B₁ can preferably be generated by a primary voltage-controlled oscillator 10, in particular by a voltage-controlled oscillator 10 based on an LC resonant circuit. The excitation reference signal S_{ref} can be generated by a first secondary voltage-controlled oscillator 11, which is embodied as a multi-phase oscillator in the exemplary embodiments. A multiplexer 13 can be used for selecting as necessary from four different output signals of the first secondary voltage-controlled multi-phase oscillator 11, which are each phase-shifted by 90° with respect to one another. Matching the operating phase to the excitation reference phase is preferably effected by injection locking of the primary voltage-controlled oscillator 10 with the first secondary voltage-controlled oscillator 11.

For the switching of the operating frequency f_{ESR}, the primary voltage-controlled oscillator 10 can optionally have applied to it a first input signal for generating the resonant frequency and, during the idle period, a second input signal for generating the idle frequency. The respective input signal of the primary voltage-controlled oscillator 10, which signal can be applied to the input-side varactor diode of said oscillator in a known manner, can be chosen such that the output or target frequency provided is adapted to the respective reference frequency of the reference oscillators 11 or 12 at least to an extent such that the frequency difference is small enough for the injection locking. The final synchronization, in particular the phase matching and optionally a fine adjustment of the output frequency of the primary voltage-controlled oscillator 10, can subsequently be effected by the injection locking.

As illustrated in the exemplary embodiments, provision can additionally be made for the operating phase of the excitation signal S also to be matched to a reference phase in the context of switching the operating frequency f_{ESR} from the reference frequency fᵣₑₛ to the idle frequency f_{idle}. For this purpose, provision can be made of a readout reference phase of a readout reference signal, which is separate from the excitation signal S and the excitation reference signal S_{ref} and is preferably generated continuously. The readout reference signal can be generated by a second secondary voltage-controlled oscillator 12. For matching the operating phase, injection locking of the primary voltage-controlled oscillator 10 with the second secondary voltage-controlled oscillator 12 can be provided for this purpose. It should be mentioned that provision can optionally be made for the readout reference phase in turn to be derived from the excitation reference phase.

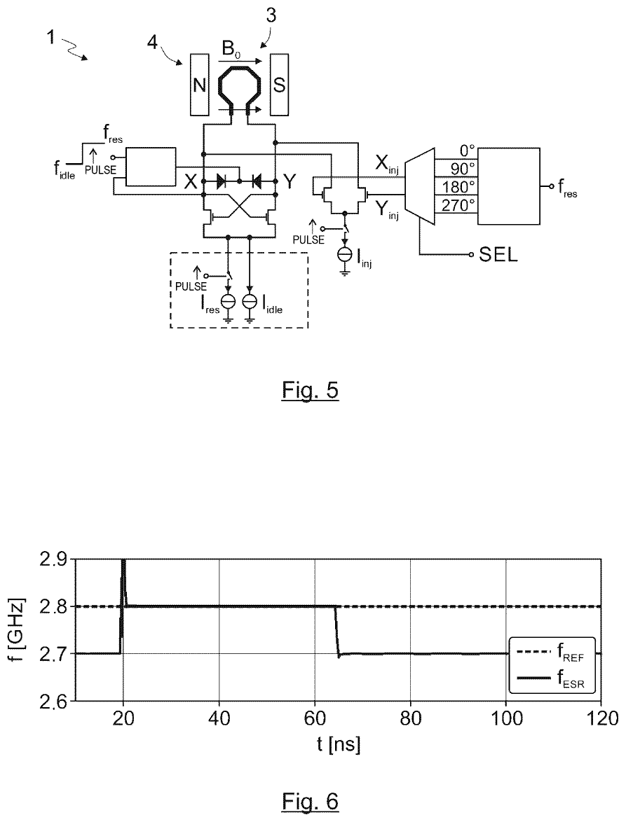

As already mentioned above, in the context of the invention, provision can also be made for increasing the amplitude of the second magnetic field B₁ in the excitation period TX by comparison with the readout or idle period RX. One exemplary implementation in this regard is indicated in FIG. 5. In this case, the bias current of the primary voltage-controlled oscillator 10 is changed during the excitation. In this way, an improved spin excitation and efficiency can be made possible, with at the same time optimum detection sensitivity using a small bias current during the idle or readout period.

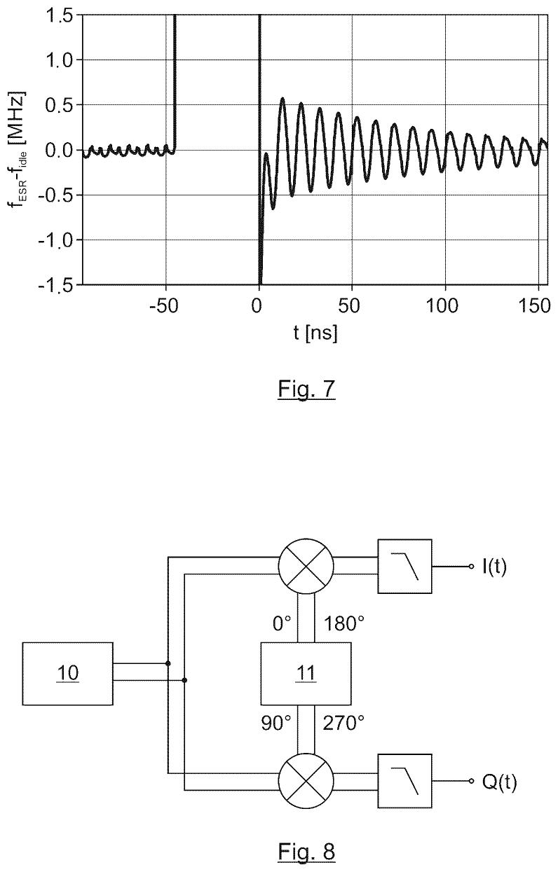

FIGS. 6 and 7 show exemplary simulation results of the proposed method. With reference to FIG. 6, it is readily discernible how the operating frequency f_{ESR} of the primary voltage-controlled oscillator 10 is adapted to the excitation reference phase of the auxiliary oscillator or of the first secondary voltage-controlled oscillator 11 within a few nano-seconds. One exemplary ESR response signal of the sample after an excitation pulse is illustrated by way of example in FIG. 7.

Finally, FIG. 8 shows another exemplary implementation for the down-conversion of the output signal of the ESR oscillator or of the primary voltage-controlled oscillator 10 using the reference oscillator for a phase-coherent detection.

1. A method for generating and/or detecting a magnetization of a sample at a sample location, for the examination of the sample by means of electron spin resonance spectroscopy or nuclear magnetic resonance spectroscopy, or for the measurement of a first magnetic field (B₀) acting on the sample at the sample location, the method comprising the steps of:
exciting an inductive assembly by an excitation signal (S) in order to provide a second magnetic field (B₁) at the sample location,
wherein the excitation signal(S) is switched cyclically between an excitation period (TX), in which an operating frequency (f_{ESR}) of the excitation signal (S) has a sample-specific resonant frequency (fᵣₑₛ), and an idle period (RX), in which the operating frequency (f_{ESR}) of the excitation signal (S) has an idle frequency (f_{idle}) different than the resonant frequency (fᵣₑₛ),
wherein an operating phase of the excitation signal (S), at least in the context of switching the operating frequency (f_{ESR}) from the idle frequency (f_{idle}) to the resonant frequency (fᵣₑₛ), is matched to an excitation reference phase of an excitation reference signal (S_{ref}), which is separate from the excitation signal (S), wherein the excitation signal (S) is generated by a primary voltage-controlled oscillator,
wherein the excitation reference signal (S_{ref}) is generated by a first secondary voltage-controlled oscillator, and
wherein said matching of the operating phase to the excitation reference phase is performed by injection locking of the primary voltage-controlled oscillator with the first secondary voltage-controlled oscillator.

2. The method according to claim 1,
wherein the primary voltage-controlled oscillator is based on an LC resonant circuit.

3. The method according to claim 1,
wherein the operating phase of the excitation signal (S), in the context of switching the operating frequency (f_{ESR}) from the resonant frequency (fᵣₑₛ) to the idle frequency (f_{idle}), is matched to a readout reference phase of a readout reference signal, which is separate from the excitation signal (S) and the excitation reference signal (S_{ref}).

4. The method according to claim 3,
wherein the readout reference signal is generated by a second secondary voltage-controlled oscillator.

5. The method according to claim 4,
wherein at least one of the first secondary voltage-controlled oscillator and the second secondary voltage-controlled oscillator is embodied as a voltage-controlled multi-phase oscillator.

6. The method according to claim 4,
wherein matching the operating phase to the readout reference phase is affected by injection locking of the primary voltage-controlled oscillator with the second secondary voltage-controlled oscillator.

7. The method according to claim 1,
wherein the primary voltage-controlled oscillator receives a first input signal for generating the resonant frequency (fᵣₑₛ) in the excitation period (TX) and a second input signal for generating the idle frequency (f_{idle}) in the idle period (RX).

8. The method according to claim 1,
wherein an at least two directly successive excitation periods (TX) progress phase-coherently with respect to one another.

9. The method according to claim 1,
further comprising the step of increasing the resonant frequency (fᵣₑₛ) by a factor of at least 1.05 relative to the idle frequency (f_{idle}).

10. The method according to claim 1,
wherein the inductive assembly is excited by the excitation signal (S) without an interruption.

11. The method according to claim 1, further comprising the steps of:
using the inductive assembly to detect a response signal of the sample during the idle period (RX) of the excitation signal (S); and
using a control device to evaluate the detected response signal.

12. The method according to claim 1,
further comprising the step of reducing an operating amplitude of the excitation signal (S) by at least 10% in the idle period (RX) relative to the excitation period (TX).

13. A magnetometer for measuring a first magnetic field (Bo) by generating and/or detecting a magnetization of a sample at a sample location, comprising:
an inductive assembly;
a control device configured to excite the inductive assembly by an excitation signal (S) in order to provide a second magnetic field (B₁) at the sample location,
wherein the excitation signal(S) is switched cyclically between an excitation period (TX), in which an operating frequency (f_{ESR}) of the excitation signal (S) has a sample-specific resonant frequency (fᵣₑₛ), and an idle period (RX), in which the operating frequency (f_{ESR}) of the excitation signal (S) has an idle frequency (f_{idle}) different than the resonant frequency (fᵣₑₛ), and
wherein, at least in the context of switching the operating frequency (f_{ESR}) of the excitation signal (S) from the idle frequency (f_{idle}) to the resonant frequency (fᵣₑₛ), an operating phase of the excitation signal (S) is matched to an excitation reference phase of an excitation reference signal (S_{ref}), which is separate from the excitation signal (S);
a primary voltage-controlled oscillator for generating the excitation signal (S); and
a first secondary voltage-controlled oscillator for generating the excitation reference signal (S_{ref}),
wherein the primary voltage-controlled oscillator is injection locked with the first secondary voltage-controlled oscillator for matching the operating phase to the excitation reference phase.

14. The magnetometer according to claim 13,
wherein the inductive assembly and the control device are arranged on a common integrated circuit.

15. A spectroscopy apparatus for examining a sample at a sample location, comprising:
a generator for generating a first magnetic field (B₀) at the sample location;
an inductive assembly; and
a control device configured to excite the inductive assembly by an excitation signal (S) in order to provide a second magnetic field (B₁) at the sample location,
wherein the excitation signal (S) is switched cyclically between an excitation period (TX), in which an operating frequency (f_{ESR}) of the excitation signal (S) has a sample-specific resonant frequency (fᵣₑₛ), and an idle period (RX), in which the operating frequency (f_{ESR}) of the excitation signal (S) has an idle frequency (f_{idle}) different than the resonant frequency (fᵣₑₛ), and
wherein, at least in the context of switching the operating frequency (f_{ESR}) of the excitation signal (S) from the idle frequency (f_{idle}) to the resonant frequency (fᵣₑₛ), an operating phase of the excitation signal (S) is matched to an excitation reference phase of an excitation reference signal (S_{ref}), which is separate from the excitation signal (S);
a primary voltage-controlled oscillator for generating the excitation signal (S); and
a first secondary voltage-controlled oscillator for generating the excitation reference signal (S_{ref}),
wherein the primary voltage-controlled oscillator is injection locked with the first secondary voltage-controlled oscillator for matching the operating phase to the excitation reference phase.

16. The method of claim 3, wherein the readout reference signal is generated continuously.

17. The method of claim 5, wherein the multi-phase oscillator is configured to generate four different output signals, which are phase-shifted by 90° with respect to one another, the method further comprising the step of using a multiplexer to select as necessary from the four different output signals of the multi-phase oscillator.

18. The method of claim 8, wherein all of the excitation periods (TX) progress phase-coherently with respect to one another.

19. The method according to claim 9, wherein the at least a factor of 1.05 comprises an at least a factor of 1.5.

20. The method according to claim 9, wherein the at least a factor of 1.05 comprises an at least a factor of 2.
